(19) United States
(12) Patent Application Publication
(10) Pub. No.: US 2011/0285399 A1
(43) Pub. Date: Nov. 24, 2011

(54) DEVICE, SYSTEM AND METHOD FOR MONITORING LINES OF GROUNDING ELECTRODES

(76) Inventors: ULISSES DE VANSCONCEL ORDONES, Passos (BR); CARLOS AUGUSTO PARDINI, Sao Jose da Barra (BR); JUAREZ NEVEZ CARDOSO, Passos (BR)

(21) Appl. No.: 13/112,786

(22) Filed: May 20, 2011

(30) Foreign Application Priority Data
May 21, 2010 (BR) PI1003307-6

(51) Int. Cl. G01R 31/11; G01R 31/14

(52) U.S. Cl. 324/509

(57) ABSTRACT

Device, system and method for monitoring lines of grounding electrodes, this invention deals with a system and a device for monitoring lines of grounding electrodes in transmission systems of electric power in direct current.

### CROSS-REFERENCE TO RELATED APPLICATIONS

This application claims priority under 35 U.S.C. §119 to Brazilian Application PI1003307-6 filed May 21, 2010, herein incorporated by reference in its entirety.

### BACKGROUND OF THE INVENTION

The present invention deals with a system and a device for monitoring lines of grounding electrodes in transmission systems of electric power in direct current.

Transmission systems of power in direct current through high voltage, acronym in English HVDC, contain two static converter stations, one acting as a rectifier and the other as inverting, which are connected respectively, at a direct current transmission line.

If the direct current system is working in monopolar operation or if it has an imbalance between the currents of the poles, the return of this current is carried by ground. This current flows through the lines of the electrodes and passes through the ground electrodes of the rectifier and inverter stations. The ground electrodes are responsible for connecting the poles to the ground, in other words, does the grounding to the current can flow to ground. Usually, the ground electrode stays at a distance of about a few kilometers to tens of kilometers of the station and it is interconnected through the lines of the electrodes.

Normally the system works in bipolar operation, in other words, with two poles in operation, and almost always works also balanced, in other words, the current which arrives to a pole return through the other pole and so doesn't flow current by the ground electrode. Only in atypical situations, it is necessary the return of current by lines of electrodes and by the ground electrodes.

Therefore, under normal conditions, it works in bipolar balanced operation.

However, the lack or malfunction of these lines can be hidden while the bipole remains in bipolar operation and balanced and when it leaves one of these conditions leads to a loss of function of a bipole, causing the shutdown including of the transmission line. Thus, it is necessary the monitoring of the system, in particular, of the line of the ground electrode to identify the problem and restrict the system due to the high possibility of interruption in the energy transmission and also take measures to restore the line of electrode.

The cost of interruption operations of a transmission energy system is extremely onerous.

Many of the current arrangements have proved ineffective. The current monitoring shows response considerably slow, regarding the mobilization of teams, partial interruption for repairs and secondary measures.

Some known solutions provide monitoring with time response that reduces the time to start the measures.

The solutions of prior art are:

LFA—Line Failure Analysis. The LFA provides monitoring of transmission lines (but not grounding) in which the line has to be disabled for then be submitted for analysis. The equipment is connected to the line in general through coupling capacitors and generates pulses, besides analyzes their reflections.

LFL—Line Failure Location. The LFL provides monitoring in live line, however the detection is made from two wave fronts generated by a failure, which migrate to the ends of the line and where they are captured and processed for identification and positioning of the failure.

The solutions of the prior art are directed to monitoring the transmission line in direct or alternating current, but not the lines of grounding, in addition, current developments show appreciable complexity as opposed to the efficiency achieved.

They are also known from the prior art the following teaching:

The method described in U.S. Pat. No. 6,518,769 B1 uses to monitor an electrode line, a balanced pulse to ground which is formed of an unbalanced pulse to ground in a “push-pull” mode that is injected into the line conductors. A curve of reflected signals is recorded coming from the signals echoed and compared with a reference dynamic curve. A sign of failure is generated when the curve exceed a tolerance band placed next to it.

In this method, it is necessary two circuits to generate two pulses of opposite polarities, a positive to be applied in a conductor of the line in relation to ground and another pulse, of opposite polarity also with application to ground to be implemented simultaneously in the other conductor of the line.

As the common mode noises (eg.: from the direct current converters) traffic in their components until the coil which makes the differentiation of two signals, any variation in the feature of each component can cause an imbalance in the read signals to record the echoed pulses (reflected) or at the pulses applied to the conductors of the line. The echoed pulses can be contaminated with common mode noises. The two circuits have to be very well adjusted to avoid noises.

Due to the use of coupling capacitors, surge suppressors (lightning-rod) etc, the equipment becomes more onerous.

The use of isolation transformer at the electrical and electronic circuit adds pulse at the readings made by the device enabling read errors.

The document of U.S. Pat. No. 5,903,155 relates to a method of measuring to determine the distance at which a failure occurred in a power transmission line HVDC. This patent document is related to that we call LFL (Line Failure Locator) for the HVDC whose principle is through sensors at the ends of the line to capture the traveling waves coming from a failure on the line and record the time difference it reaches to each of these sensors and then calculate the distance of the occurrence as a function of time. This equipment is not used to monitor the line of the electrode that is grounded by the ground electrode, then the tension of this line is practically zero and does not generate traveling waves in a ground failure, short-circuit between line conductors or breakage of the conductor cable of the line, enough to excite the sensors.

The document of U.S. Pat. No. 4,151,460 relates to a ground failure detector of high resistance and a locator for the multiphase electrical systems. This patent document aims to monitor multiphase electrical systems. The idea is applied to multiphase electrical systems, in other words, of the alternating current. Apply signs in the neutral of the multiphase current switched to locate failures at the ground. Therefore, does not apply in the lines of the ground electrode of direct current.

The document of U.S. Pat. No. 5,428,295 relates to a failure locator for use in location of grounding failures in high resistance in concentric electric power cables and grounding. This patent document was developed to locate electrical failures in coaxial cables which principle is to apply pulses in a frequency of 512 kHz with an amplitude of 4 kV peak to peak. Not been made for a grounding airline for use with the energized line of the converter stations of the direct current.

The patent document CA 1,114,892 relates to a method to identifying one pole of a transmission station in direct current that is out of service. This patent document is a method to take away a pole of operation of a HVDC Transmission Station. Not applicable in a line of electrode of the ground of converting.

The patent document WO 01/84687A2 relates to a system of failure detection of sensible grounding for use in electricity compensated networks distribution. This patent document includes a sensible detection system of the failures for the ground for use in distribution networks of electric power compensated, in other words, designed for alternated current systems, which have zero sequence. Not applicable on lines of electrode of the ground of the direct current that are grounding and have no zero sequence.

### BRIEF DESCRIPTION OF THE INVENTION

The object of this invention is to provide a method for monitoring a line of ground electrode of a HVDC transmission system and a device to use this method and, with it, to simplify the hardware and eliminate the disadvantages previously reported.

According to the method of this invention, the electric pulse is applied directly to the conductor cables of the ground electrode. The pulse is applied from a cable to another, in other words, has no reference to ground.

Thus, part of the circuit for the generation and application of electrical pulse, as well as the monitoring of pulses, are all in the line potential, and so there isn't movement of currents derived from common mode noises. Soon, the noises generated by CC converting, by switching, etc., and even influences of the grounding electrode are not seen by the device. The potential of the device floats along with the common mode noises.

Since there is no movement of common mode noises, the monitoring of the reflected pulses is immune to the imbalances of the device components, thereby bringing quieter information from applied and reflected pulses (echoes).

The pulses generated by the device does not interfere in the operation of the HVDC system, since it is in a closed “loop” between the two conductors of the line of the electrode from the substation in the common point from where beginning the two power cables that it is called here of “arm” until the end of the line where the two conductor cables come together in a single electrical point again in the connection to the ground electrode.

As the pulse is generated and applied directly in the line it appears well defined, without interference from common mode and with very little noises.

As the device is in the potential of the line, become unnecessary the equipment of the coupling capacitors type, surge suppressors (lightning-rod), and/or others in the circuit, reducing a lot the costs.

In this project, it is also unnecessary the filters in series or in parallel with the line.

Due to the main device be in the line potential, the circuit becomes extremely simple, not requiring precise adjustments in the electronic components such as at the system that uses the “push-pull” mode that requires duplication of the circuit. Also, there is not a concern to eliminate DC components (offset) in the circuit.

In the monitoring of the pulses, it can be used the own energy of pulse, applying it in a photo-transmitters as LED, leading the information through optical fibers to a photo-receiver in analog way, which makes this part of the circuit extremely simple. One advantage is that saves energy in the device, needing energy only to generate the pulse to be applied.

Another advantage is that the information coming out of the device at high voltage go directly to the receiver that is at ground potential. This becomes possible due to the optical fibers are electrically insulating. The optical fiber cable can have more than one kilometer in length, without causing significant losses, making it possible to take the information directly to a substation control room.

Another way to send the information is through the radio frequency by amplitude or frequency modulation (analogical or digital signal). But it spends more energy and it is necessary to strengthen the power supply.

Another way is through an antenna to pick up the pulse on the line and get in a radio receiver that sends a pulse to this scanner and to the processor. Thus the monitoring is outside the main device (which is on high voltage), thereby saving energy. The antenna is more susceptible to interference.

To feed the main device, which is in potential of the line, it can be used solar panels with accumulator (battery) scaled to ensure the supply during the night and ensure when you have several days overcast, no sun. A lamp, as light source for the solar panels can greatly reduce the sizing of the accumulator or delete it if desired.

Another way to feed it is through the emission of energy by light through the optical fiber itself. The transmitter stays at ground potential supplied by the power grid and connected at one end of optical fiber and the receiver's power stays in the main device on the potential of the grounding line at the other end of the fiber, and thus convert light energy into electricity.

The analysis of the signals is done by software as follows: In the time axis in the period between the end of the applied pulse and the beginning of the reflected pulse in a line without fail, we use a single band of tolerance as a way to detect if there was a lack in line. We put two limits represented by two lines, one defining the upper limit and another defining the lower limit. The tolerance band is fully programmable by user and can alter the levels and curves from the beginning of the pulse applied to the end of the reflected pulse from the end of the line.

In the period related to the applied pulse, the amplitude of said pulse is monitored to detect if there was any defect in the equipment. If the pulse is below a certain value it generates an alarm indicating that the equipment is failing.

The program installed on the computer reads the curve of the data acquisition board and makes an average with a specified number of previous curves readings, creating an average curve.

This average curve works inside a band and, if it exceeds the positive or negative limits, it means that there was a problem in the line and occurred at a distance proportional to that moment. The analysis should be made from the closer pulse to the applied pulse, since they may appear multiple reflections, which will appear with multiple distances of the first reflection. Normally, the occurrence of failure, the pulse echoed for the end of the line decreases the amplitude, may even disappear.

It can be observed that the curve presented by this device has no pulse reflection caused by the device itself due to the lack of isolation transformer in its circuit.

### OBJECTIVE OF THE INVENTION

This invention aims to provide a system with a device for monitoring lines of grounding electrode in electric power transmission systems without the limitations discussed above.

### DESCRIPTION OF THE FIGURES

FIG. 1—Shows the block diagram of an example of a device of the invention in a line of electrode of a bipole of an HVDC Transmission System.

FIG. 2—Shows with more details a basic circuit of a Pulse Generator related to FIG. 1.

FIG. 3—Shows with more details a basic circuit of a Transducer related to FIG. 1.

FIG. 4—Shows the curve of the signals of generated pulse and reflected pulse in a line of 67 km in length.

FIG. 5—Shows a diagram of a bipole of the link of direct current, comprising a station with a frequency of 50 Hz, the transmission line with more or less 600 kVdc and another station with a frequency of 60 Hz.

FIG. 6—Shows the drawing of how is an assembly of a typical system for monitoring line of ground electrode at one of the power poles.

FIG. 7—Shows an assembly sketch of the equipment on a power pole of the line of electrode.

FIG. 8—Shows a scheme from the power unit on the power pole, composing by solar panel and battery.

FIG. 9—Shows a monitoring system with two lines of electrodes, with monitoring in a single computer and alarm exits for a supervisory system.

### DESCRIPTION OF THE PREFERRED ASSEMBLY OF THE INVENTION

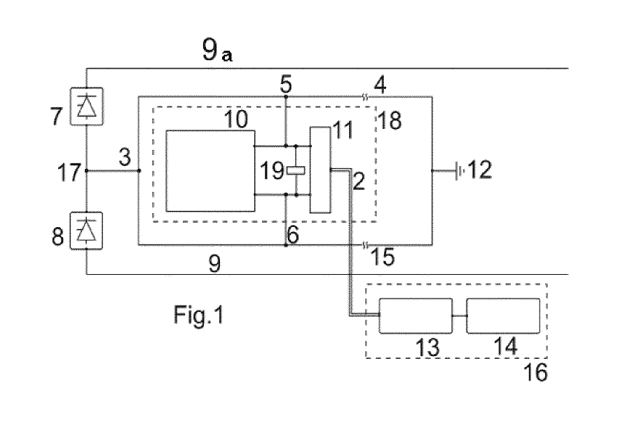

FIG. 1 shows a device composed by two units, one called main device (18) and other secondary device (16), as an example of this invention to monitor the line of the ground electrode (4 and 15) of a bipole of an HVDC transmission system, which aims to give an idea of the single or only one of the bipoles of the converter station represented in this figure.

The bipole of an HVDC system is a DC transmission system with two poles per converter station and are connected through a DC transmission line with two conductors, with a bipole at each end, and each bipole converter station has two poles (7 and 8) which are connected electrically in series by a bus (17). Each pole usually has one or two static converters.

In normal operation of a bipole, the DC current does not return by grounding. When that, for some reason, have to operate with only one pole of the bipole, which is called monopolar operation either by a defect or maintenance of the other pole, the current passes across the arm (3) and divides into two conductors of the line (4 and 15) to the electrode of the ground (12). Usually the line of electrode has up to 100 km extension.

The bipole of the other station is also operating with a monopolar current and also circulates through the line of electrode of it.

To protect the main device (18) against problems like lightning or maneuvers surges, it can be used, for instance, varistors (19) to protect the main device. This device is for low voltage which dimensions are relatively small.

To monitor the line of the electrode, composed by two conductors (4 and 15), a typical example of the device is shown in FIG. 1, according to this invention. The main device (18) is composed by a pulse generator (10) and a transducer (11) that reads the generated and reflected pulses (echo) for the monitoring. It sends the data through optical fibers to the secondary device (16). The secondary device (16) is composed by an optical-digital converter (13) and a computer (14) that are on ground potential of the. These two devices are interconnected by two optical fibers as a way of transport to the sampled signals.

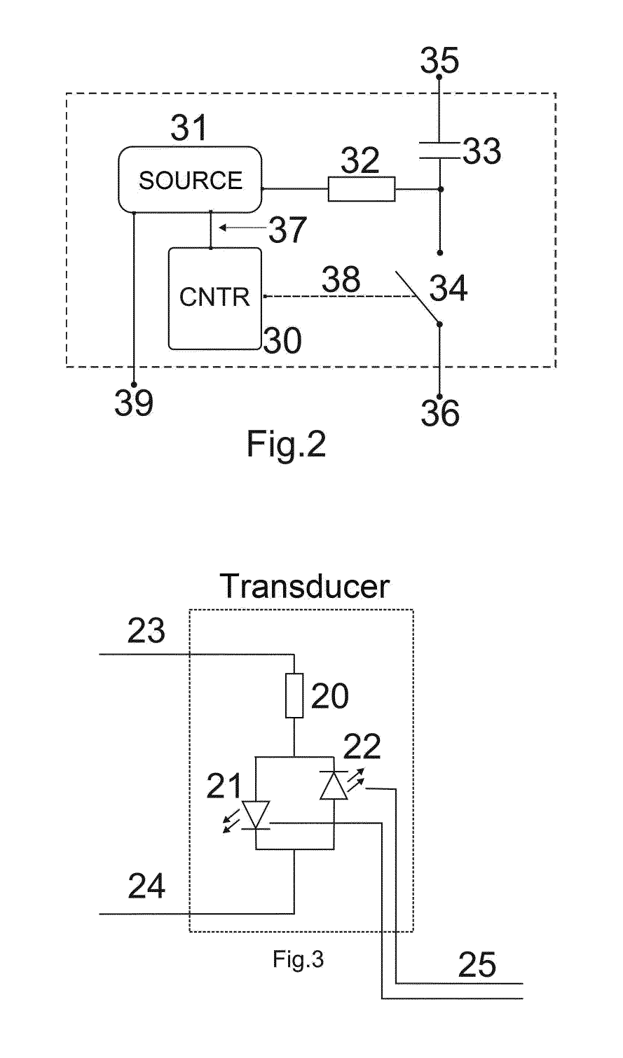

A basic example of how the pulse generator (10) could be is shown in FIG. 2. It is composed by a direct voltage source (31), a controller circuit (30), an electronic switch (34), and a capacitor (33).

For the generation of the pulse, it starts with the electronic switch (34) open, the controller unit (30) activates the power supply by the control line (37) which circulates an electric current through the resistor (32), charging the capacitor (33) and closing the circuit through the line of electrode to the negative reference of the source (39).

Soon after, the controller (30) disables the source through control line (37) and then closes the only electronic switch (e.g., thyristor), through control line (38).

At this moment, the potential of the capacitor is applied between the conductor cables of the line of electrode, applying the pulse in this. The wave front is then propagated in both directions of the line. One goes into the ground electrode (12) and another toward the arm (3) which, to pass by, changes polarity and passes again through the points (5 e 6), composing then the second half-cycle of the applied pulse. For this, the assembly of the main device in the line of electrode should be far from the arm (3) a quarter of the wavelength of the fundamental frequency of the applied pulse. The pulse time for going and coming back toward the arm is the same of half-cycle and thus it completes the pulse wave propagated toward the ground electrode. That's why it is applied only the positive pulse in the line.

It's suggested as an example the use of a power pole of the line already existed for the installation of the equipment; this power pole should be at a distance of 75m closest to the arm, which corresponds to the frequency of 500 kHz, or periods of 2 uS. For a very different distance, it should be made an adjustment in the main device.

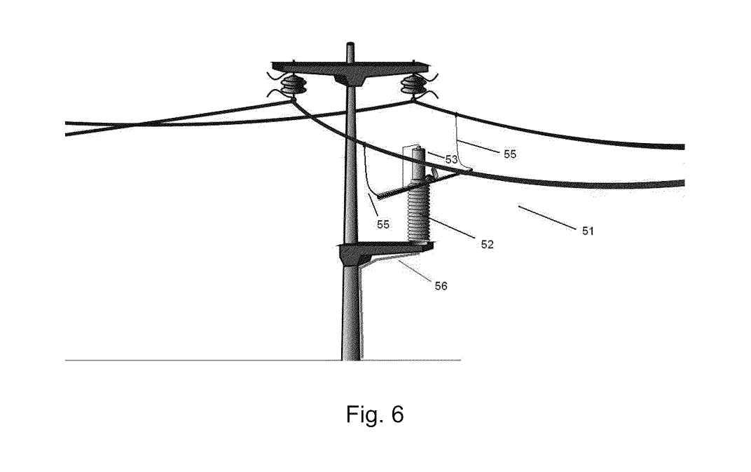

It can be assembled a support fixed to the power pole and an isolator fixed above the support, with the main device above the isolator (see the example in the FIG. 6).

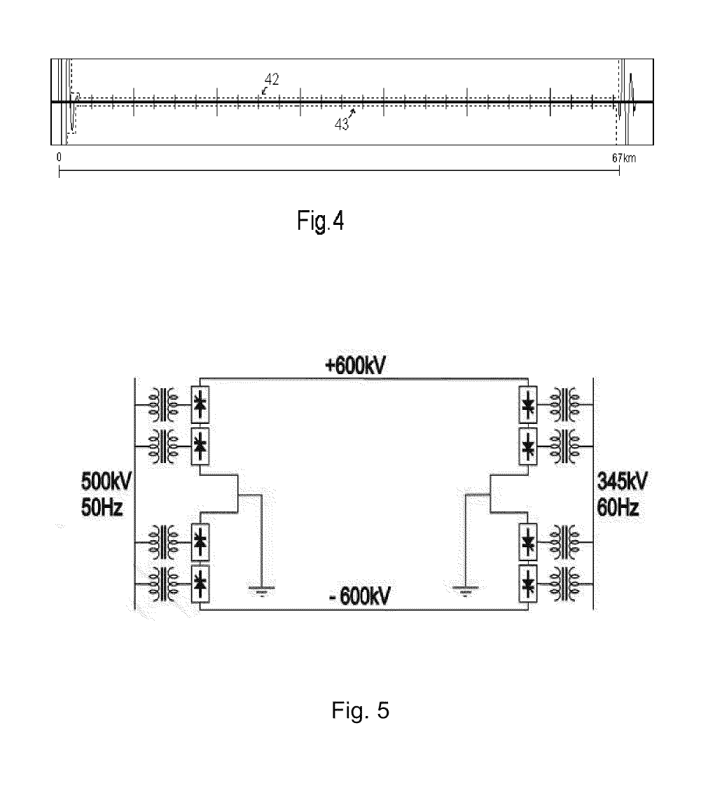

The device (13) of this example receives the optical signal coming from the transducer (11) of the main device (18) through two optical fibers (2) and makes the change of optical to analog by using a photo-receptor. This analog signal is then changed for digital through an A/D converter by using, for instance, a data acquisition board. The computer (14), through software, reads this digital signal and processes it, presenting the results in its screen. The sampling frequency of the A/D converter depends on the length of the line of electrode (4 and 15), depends also of the memory available for storing the data acquisition board. 1024 sampled values of 8-bit words are sufficient. See a sample of an acquisition of pulse applied and reflected in a line of 67 km in the FIG. 4.

The time between application of the pulse on the line, which is the pulse on the left in the FIG. 4, until the reflected pulse (echoed) at the end of the line, which is the one on the right, it is proportional to the length of the line, remembering that the propagation speed of the pulse in the line is almost the speed of light, and that the time is the round trip on the line. If a failure in the line occurs, a reflected pulse will appear at a time proportional to the distance of the failure to the device.

The time scale on the X axis can be scaled in order to present numerically the reading of distance to facilitate analysis by the user.

The program installed on the computer reads the curve of the data acquisition board and makes an average with a specified number of previous readings of curves, creating an average curve.

This average curve works inside a band and, if it exceeds the positive (42) or negative (43) limits, it means that there was a problem in the line and occurred at a distance proportional to that moment. The analysis should be made from the closer pulse to the applied pulse, since they may appear multiple reflections, which will appear with multiple distances of the first reflection. Normally, the occurrence of failure, the pulse echoed for the end of the line decreases the amplitude, may even disappear.

It may be noted that the curve presented by this device has no reflection due to lack of isolation transformer in this invention.

A method for monitoring a line of grounding electrode of the bipole of a system for transmitting high voltage direct current (HVDC), where the line of the electrode has two conductors and which method comprises:

generation of an electric pulse without application to the ground, but directly in the line conductors, from a conductor to another.

the electric pulse is applied in the line by the device.

reading of the generated pulse applied and the reflected pulse (echoed).

filtering of the average type of the last reading with some previous readings.

checking if the curve is within a pre-determined range (normal operation reference), according to the time axis and showing of the results in the computer screen.

calculation and presentation of the failure distance in the line to the operator and generation of a failure signal to the supervisory system, if the curve exceeds the reference settled.

According to this invention, the amplitudes of the applied and reflected pulses are monitored for said alarms. The tolerance bands for upper and lower to the curve is programmable and is generated according to parameters of operation of the line of electrode, not being necessary to create other static curves for each condition of operating mode of the HVDC system.

The components of pulse generator of this invention are predefined according to distance from the arm to the installation place of said device, which should be about ¼ of the wavelength.

Another feature of this invention is that there is no offset in the pulse generator and therefore is not necessary to make adjustments applied.

Another feature of the present invention is that the pulse generator circuit is not applied to ground, being assembled on the potential of the line. Larger-size equipment is not necessary, as a lightning rod and the large coupling capacitors. Therefore, as the device is not applied to ground, it is simpler and cheaper.

A pulse generator and a transducer for reading and transmitting the waveform are assembled on the potential of line. The device has a transducer that reads the differential voltage between two line conductors and this waveform modulates, in amplitude, the light through a photo-transmitter; this light is sent to a receiving unit via optical fiber. The receiving unit uses a regular computer, eliminating the production of micro-processed boards. The device has an optical/serial converter that changes the optical signal to an analog electric signal through photo-receptors. The analog signal is then changed to digital signal, using an A/D converter, and sent to a computer through serial communication. The memory used for registration of failures for analysis after these failures is treated in the software installed on the computer.

The two optical fibers are used to carry information from the transducer pulses of device installed in the line to the optical/serial converter in the operator room.

This invention is described in an illustrative way, however, it is not in any way limiting the scope here claimed. At the end, a list is provided for identification of the parties represented in the attached schematic figures, as well as those that mention said example.

Although instructive, the example of this invention allows variations and/or modifications still included in the scope now claimed, therefore, some parts listed may be omitted and/or modified without affecting the scope of this invention.

### Example

### Monitoring of Lines of Grounding Electrodes

The example provided refers to FIGS. 6 to 9 of the invention.

There are four lines in the HVDC link: 2 in Ibiúna (a city in the state of São Paulo/Brazil), of 67 km size and 2 in Foz do Iguaçu (a city in the state of Paraná/Brazil), of 15 km size. The loss of any of them may represent a sudden falling of 3.150 MW. Possible failures can be unobserved when the bipoles are in balanced working, in other words, during most of the time. The lines are located in populated area, being subject of an attempted theft and vandalism.

In February 2004, theft of cable lines of the electrodes occurred in Ibiúna, totaling approximately 3850 m of cables stolen. FURNAS, at that time, had no system to monitor the integrity of the lines.

Facts like these mean a serious risk of outages for the electric system. Therefore, a system for monitoring lines of grounding provides a way to act proactively in anticipation of failure scenarios. The system for monitoring failures in a line of grounding comprises a device, according to this invention, in which an elevator of voltage unit stores energy in a capacitor. When the appropriate level of voltage is achieved, a thyristor is discharged, thereby generating a pulse of high power, but lasting only a few microseconds. This impulse is applied between the power supply cables, from some distance from its end. A digital data acquisition system captures the waveform generated, containing the pulse and its reflection in the connection with the electrode, transmitting the oscillogram to a computer via RS232 modem, by optical fiber or radio frequency. The software presents this oscillogram and makes the analysis of it, identifying the type of failure detected eventually.

### LIST OF REFERENCE NUMBERS IN THE FIGURES

FIG. 1 (Diagram of the Device):
9 and 9a: Conductors of the direct current
3: Arm between the neutral bar and the conductors of the line of electrode
4 and 15: Conductors of the ground electrode
5 and 6: Cables of the main device connected to the line of electrode.
7 and 8: Static converters of direct current
10: Pulse generator device
11: Transducer (voltage between the line conductors for optical signal)
12: Ground electrode
13: Optical-to-digital converter (serial)
14: Computer
16: Secondary device
17: Connection between the converter and neutral bar
18: Main device
19: Component eliminator of bouts

FIG. 2 (Pulse Generator):
31: High voltage source
32: Resistor
33: Capacitor
34: Electronic switch
35 and 36: Exit of the pulse generator
37: Line of control (actives the source)
38: Line of control (controls the electronic switch)
39: Reference of potential

FIG. 3 (Transducer)
20: Resistor
21 and 22: LED (transmitter connected to the fiber optic)
23 and 24: connections (connected to the potential of conductor cables of the line)
25: Optical fibers

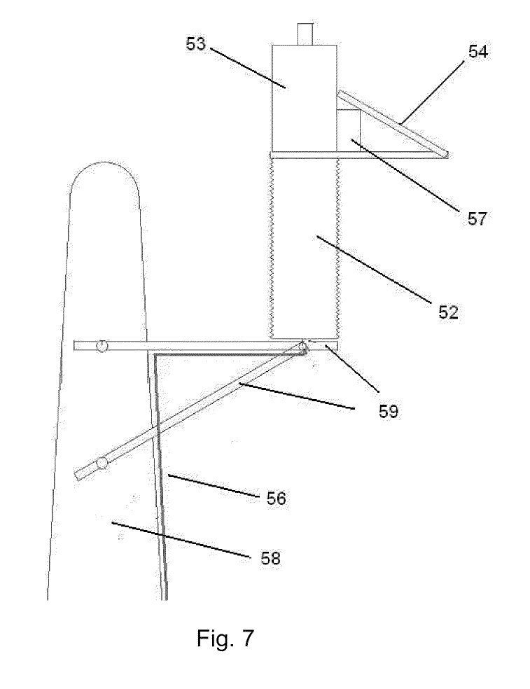

FIGS. 6 and 7 (Non-Limitative Example of a Device)
51: Main device
52: Isolator
53: Electronic part of the device
54: Solar panel
55: Cables of the main device connected to the line of electrode
56: Optical fibers
57: Accumulator (battery)
58: Line of electrode power pole
59: Support of the device in the main power pole

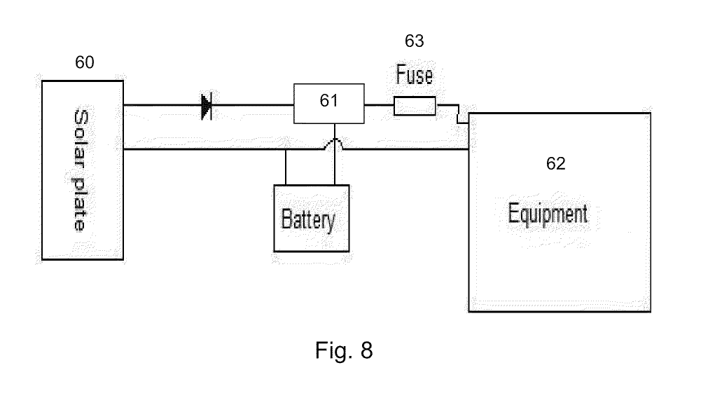

FIG. 8: Non-Limitative Example for Feeding of the Main Device (For the Equipment in the Potential of the Line of Electrode)
60: Solar panel
61: Accumulator (battery)
62: Main equipment
63: Protection fuse

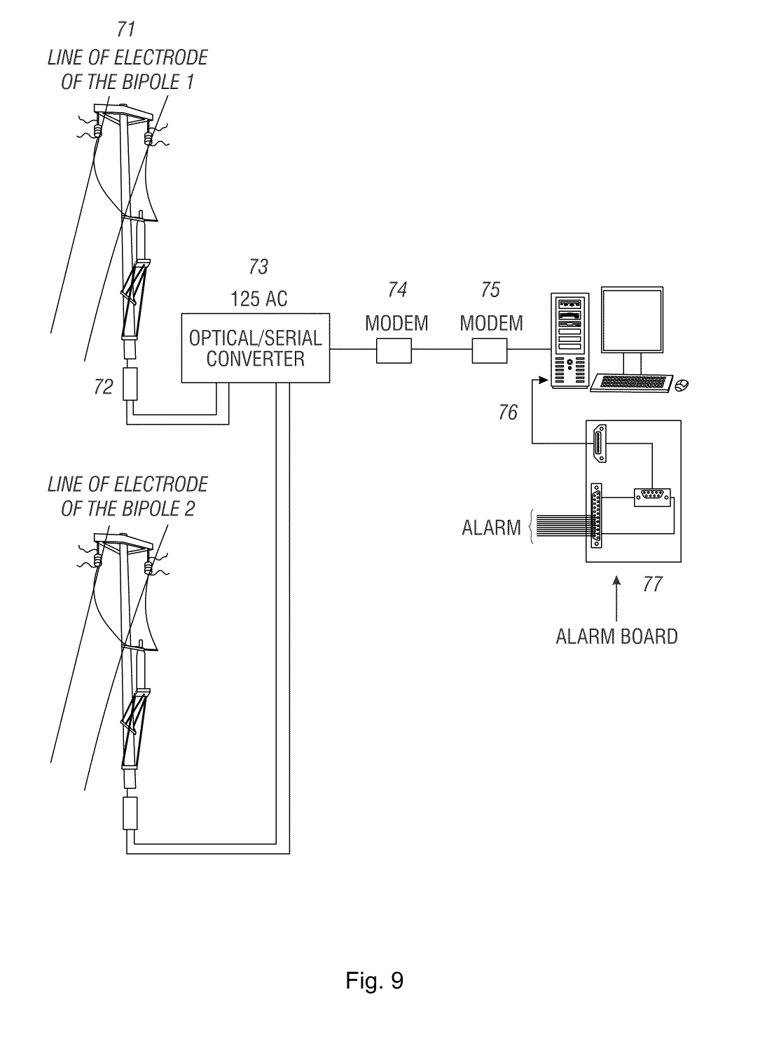

FIG. 9: Non-Limitative Example of Assembly of the System of Monitoring for Two Lines of Electrodes Comprised by Alarm Exits.
71: Line of electrode of the Bipole 1
72: Line of electrode of the Bipole 2
73: Optical/serial converter
74 and 75: Communication modem
76: Exit of the alarm signals
77: Alarm board

What is claimed is:

1. Device for monitoring lines of grounding electrodes, comprising a base (2), means of detection (3), solar panel (4), a detection line (5) connected to the line of grounding, wherein the device (1) is integrated in a monitoring system of failures in lines of grounding through a fiber optic cable (6).

2. Device, according to claim 1, wherein the base (2) comprises a piece of insulating material.

3. Device, according to claim 1, wherein the means of detection (3) comprise a metal box, which includes analyzer means.

4. Device, according to claim 3, wherein the analyzer means comprise a routine for monitoring the line of grounding, collecting information from the line signs, and transmission of information via optical fiber.

5. Device, according to claim 1, wherein the feeding comprises a solar panel (4) and a battery (7) complementary.

6. System for monitoring lines of grounding electrodes, comprising: a first unit of the device positioned in the line of electrode of a first bipole; and a second unit of the device positioned in the line of electrode of the second bipole.

7. System, according to claim 6, wherein the readings from voltage variations between the conductor cables of the line of grounding are received on an optical/serial converter.

8. System, according to claim 7, wherein the serial signal generated is transmitted through serial cable to a remote unit of monitoring.

9. System, according to claim 6, wherein the optical signal received in the remote unit of monitoring is associated to a condition out of normality, compared with threshold levels inserted as reference.

10. System, according to claim 9, wherein the optical signal compared to the threshold levels of reference generates an alarm signal associated to a pre-established measure.

11. Method for monitoring the line of grounding electrode of the bipole of a transmission system of high-voltage direct current (HVDC), wherein the line of electrode has two conductors, comprising: —generation of an electric pulse without application to the ground, but directly in the line conductors, from a conductor to another; —the electric pulse is applied in the line by the device; —reading of the generated pulse applied and the reflected pulse (echoed); —filtering of the average type of the last reading with some previous readings; —checking if the curve is within a pre-determined range (normal operation reference), according to the time axis and showing of the results in the computer screen; —calculation and presentation of the failure distance in the line to the operator and generation of a failure signal to the supervisory system, if the curve exceeds the reference settled.

12. Method, according to claim 11, comprising an average of the curves values.

13. Method, according to claim 11, wherein the amplitudes of the pulses applied and reflected are monitored for the said alarms and the tolerance bands upper and lower to the curve are programmable by user.

14. Method, according to claim 11, wherein a tolerance band is also generated according to parameters of operation of the line of electrode, not being necessary to create other static curves for each condition of operating mode of the HVDC system.

15. Method, according to claim 11, wherein the device is adjusted to the applied pulse, according to the distance of the arm until the installation of said device, which is about ¼ of the wavelength.

16. Method, according to claim 11, wherein the main device not applied to ground is connected directly to conductor cables of the line of electrode and the pulse generator and the transducer are in the potential of the line.

17. Method, according to claim 11, wherein the main device has a transducer that makes the reading of the differential voltage between the two conductors of line and this kind of wave modulates, in amplitude, the light through a photo-transmitter; said light is sent to a receiving unit via optical fiber.

18. Method, according to claim 11, wherein the device has an optical/serial converter that converts the optical signal to an analog signal through a photo-receptor.
